(19) United States
(12) Patent Application Publication
(10) Pub. No.: US 2025/0266210 A1
(43) Pub. Date: Aug. 21, 2025

(54) MULTILAYER CERAMIC CAPACITOR AND CIRCUIT BOARD

(71) Applicant: TAIYO YUDEN CO., LTD., Tokyo (JP)

(72) Inventors: Yasutomo SUGA, Tokyo (JP); Takashi SASAKI, Tokyo (JP); Yuji TOMIZAWA, Tokyo (JP)

(73) Assignee: TAIYO YUDEN CO., LTD., Tokyo (JP)

(21) Appl. No.: 19/053,013

(22) Filed: Feb. 13, 2025

(30) Foreign Application Priority Data
Feb. 15, 2024 (JP) 2024-021193
Feb. 3, 2025 (JP) 2025-016133

(51) Int. Cl. H01G 4/232; H01G 4/30; H05K 1/18

(52) U.S. Cl. CPC H01G 4/232; H01G 4/30; H05K 1/181; H05K 2201/10015

(57) ABSTRACT

A multilayer ceramic capacitor pertaining to one aspect of the present invention comprises: a rectangular solid element having a laminate in which ceramic layers and internal electrodes mainly composed of metal are stacked alternately; a protective section covering the surface of the laminate; and an element having a plurality of via conductors, disposed so as to penetrated said ceramic layers in the stacking direction of said laminate, at least one end of which reaches the surface of the protective section and is electrically connected to said internal electrodes; and a plurality of terminal electrodes disposed on a mounting surface that, among the surfaces that form the front surface of said element, faces the circuit board when mounted on said circuit board; wherein all of the plurality of terminal electrodes are electrically connected to said via conductors and arranged with a spacing of 10 μm or more from the outer edge of said mounting surface.

### CROSS-REFERENCE TO RELATED APPLICATIONS

This application claims the benefit of Japanese Application No. 2025-016133, filed Feb. 3, 2025 and Japanese Application No. 2024-021193, filed Feb. 15, 2024, in the Japanese Patent Office. All disclosures of the documents named above are incorporated herein by reference.

### BACKGROUND OF THE INVENTION

### 1. Field of the Invention

Aspects of the invention relate to a multilayer ceramic capacitor and a circuit board.

### Description of the Related Art

In recent years, as electronic devices such as smart phones have become more sophisticated, the semiconductors that they use have also become more sophisticated. The higher the performance of a semiconductor, the more susceptible it is to noise, and in order to eliminate this noise, multilayer ceramic capacitors (MLCCs) are used as decoupling capacitors.

With a multilayer ceramic capacitor for use as a decoupling capacitor, in order to reduce equivalent series inductance (ESL) we know that a plurality of conductors, which electrically connect external electrodes arranged on the main surface with internal electrodes, can be provided for each polarity, and are arranged so that the magnetic fields generated by the flowing currents cancel each other out (D1, D2).

We also know that in a multilayer ceramic capacitor, when the capacitor is mounted on a circuit board, external electrodes are arranged only on the mounting surface that comes into contact with the circuit board, thereby suppressing the spreading area of the solder connecting the multilayer ceramic capacitor to the circuit board and reducing acoustic noise (D3).

### PRIOR ART DOCUMENTS

### Patent Documents

[D1] Japanese Unexamined Patent Publication No. H07-201651 A
[D2] Japanese Unexamined Patent Publication No. 2006-135333 A
[D3] U.S. Pat. No. 10,617,008

### SUMMARY OF THE INVENTION

### Problem(s) to be Solved by the Invention

Because the noise elimination effect of a multilayer ceramic capacitor will be greater the closer it is to a semiconductor, low-profile multilayer ceramic capacitors (low-profile MLCCs) with a low element height are sometimes mounted on the back side of a circuit board on which semiconductors are equipped. The element heights of these low-profile MLCCs must be less than the distance between the circuit board on which the semiconductor is equipped and the motherboard on which the circuit board is mounted, so there is a demand for a device that can accommodate cases where the distance is 100 μm or less.

Multiple multilayer ceramic capacitors are often used for the noise elimination mentioned above, in order to enhance the noise elimination effect. When mounting a plurality of low-profile MLCCs to the back side of a circuit board on which a semiconductor is mounted, they will need to be arranged through the gaps in the ball grid array (BGA) that connects the circuit board to the mother board, which can result in the spacing between the low-profile MLCCs becoming extremely narrow.

In the conventional multilayer ceramic capacitor 100′, as shown in FIG. 4, terminal electrodes 40 (40a and 40b) are arranged so as to contact the outer edge of mounting surface 11. The lands of the circuit board on which the multilayer ceramic capacitor 100′ is mounted are formed to be larger than the terminal electrodes 40 (40a and 40b), and therefore are arranged to protrude from the element in a planar view, as shown in FIG. 11 of D3. Because of this, even when multiple elements are mounted in close proximity, there is a limit to how narrow the mount spacing can be. In addition, when mounting on a circuit board using solder paste, the solder will wet and rise on each surface perpendicular to the mounting surface of the multilayer ceramic capacitor, forming fillets, which also prevents the mount spacing between elements from being narrowed.

This invention has been made in order to solve the problems described above, and its purpose is to provide a multilayer ceramic capacitor that enables narrow element spacing when mounted on a circuit board, and a circuit board on which the mounted elements are mounted with a narrow spacing.

### Means for Solving the Problem(s)

The inventors conducted various tests in order to solve the problems described above, and found that the stated purpose can be achieved by arranging the plurality of external electrodes of a multilayer ceramic capacitor on the mounting surface that has the largest area among each of the areas forming the surface, and with a predetermined spacing from the outer edge of said mounting surface, and thereby implementing the present invention.

That is to say, the 1st aspect of the present invention for solving the problem described above is a multilayer ceramic capacitor comprising: a rectangular solid element having a laminate in which ceramic layers and internal electrodes mainly composed of metal are stacked alternately; a protective section covering the surface of the laminate; and an element having a plurality of via conductors, disposed so as to penetrated said ceramic layers in the stacking direction of said laminate, at least one end of which reaches the surface of the protective section and is electrically connected to said internal electrodes; and a plurality of terminal electrodes disposed on a mounting surface that, among the surfaces that form the front surface of said element, faces the circuit board when mounted on said circuit board; wherein all of the plurality of terminal electrodes are electrically connected to said via conductors and arranged with a spacing of 10 μm or more from the outer edge of said mounting surface.

A 2nd aspect of the present invention for solving the problem above is a circuit board carrying the multilayer ceramic capacitor according to the 1st aspect, wherein all lands are electrically connected to the plurality of terminal electrodes, being covered by the multilayer ceramic capacitor in a planar view.

Furthermore, a 3rd aspect of the present invention for solving the problem described above is a circuit board carrying a plurality of the multilayer ceramic capacitors according to the 1st aspect, wherein the spacing between adjacent multilayer ceramic capacitors is 50 μm or less.

### Effect of the Invention

According to the present invention, it is possible to provide a multilayer ceramic capacitor that enables narrow element spacing when mounted on a circuit board, and a circuit board on which the mounted elements are mounted with a narrow spacing.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic drawing (perspective view) showing the structure of a multilayer ceramic capacitor according to a 1st embodiment of the present invention.

FIG. 2 is a cross-section view taken along the line A-A (the LT cross section view) in FIG. 1.

FIG. 3 is a cross-section view taken along the line B-B (the WT cross section view) in FIG. 1.

FIG. 4 is a cross-section view (LT cross section view) showing the terminal electrode arrangement of a conventional multilayer ceramic capacitor.

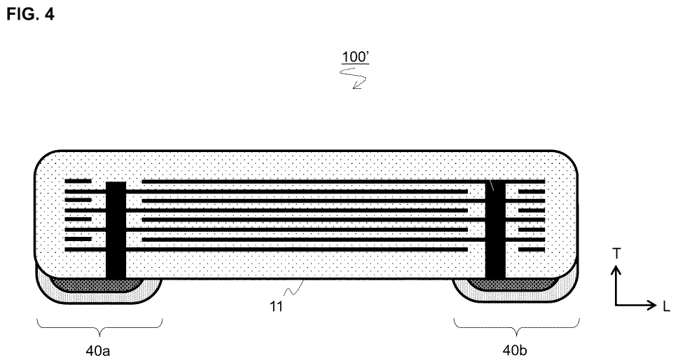

FIG. 5 is a schematic drawing (perspective view) showing the structure of a multilayer ceramic capacitor according to a 2nd embodiment of the present invention.

FIG. 6 is a schematic drawing (LT cross section view) showing the structure of a multilayer ceramic capacitor according to a 3rd embodiment of the present invention.

FIG. 7 is a schematic drawing (WT cross section view) showing the structure of a multilayer ceramic capacitor according to a 4th embodiment of the present invention.

FIG. 8 is a schematic drawing (LT cross section view) showing the structure of a circuit board according to a 5th embodiment of the present invention.

FIG. 9 is a schematic drawing (LT cross section view) showing the structure of a circuit board according to a 6th embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The configuration and effects of the present invention will be explained below, together with its technical concepts, with reference to the drawings. Although its mechanism of action includes assumptions, the correctness of these assumptions does not limit the present invention.

### Multilayer Ceramic Capacitor

### 1st Embodiment

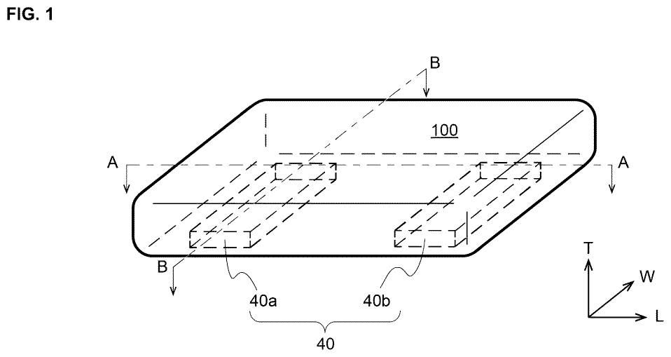

An embodiment of a multilayer ceramic capacitor according to the present invention is shown in FIGS. 1 through 3 as the 1st embodiment. Multilayer ceramic capacitor 100, according to the 1st embodiment, has a rectangular parallelepiped shape and where each pair of faces are perpendicular to three mutually perpendicular axes, i.e. the L axis, which is in the length direction, the W axis, which is in the width direction, and the T axis, which is in the height direction. The rectangular parallelepiped is not limited to a mathematically defined rectangular parallelepiped, and may have any shape that is recognized as a rectangular parallelepiped when the overall shape is observed. Therefore, a rectangular parallelepiped in this disclosure also includes those with rounded edges and corners, those with curved edges, and those that have constituent faces that surfaces with a small curvature. The length (L) dimension, width (W) dimension and height (T) dimension of ceramic capacitor 100 can each independently take any value.

The dimensions of multilayer ceramic capacitor 100 are, for example, an L-direction measurement of 200 μm to 2000 μm, a W-direction measurement of 100 μm to 2000 μm, and a T-direction measurement of 30 μm to 220 μm, with a W/L value, the ratio of the W-direction measurement to the L-direction measurement, of 0.3 to 1.0. It is preferable for the L-direction measurement to be 400 μm to 1200 μm, the W-direction measurement to be from 400 μm to 1200 μm, and the T-direction measurement to be from 40 μm to 150 μm, with a W/L value, the ratio of the W-direction measurement to the L-direction measurement, of 0.4 to 1.0. It is more preferable that the T-direction measurement be 100 μm or less, because this allows the spacing between the circuit board and the motherboard on which it is mounted to be narrowed even when mounting on the back of the circuit board (the side opposite the one on which the semiconductor is mounted).

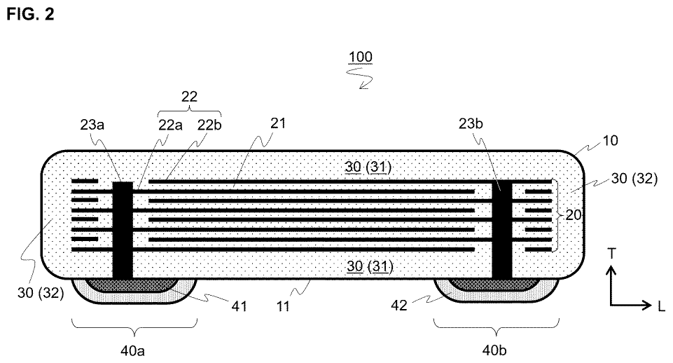

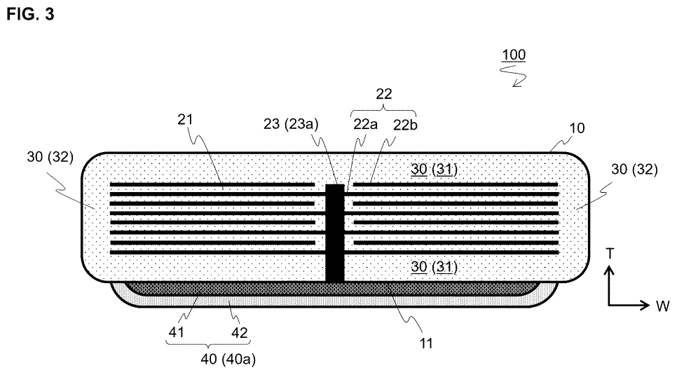

As schematically shown in its cross section views FIG. 2 (the LT cross section) and FIG. 3 (the WT cross section) the multilayer ceramic capacitor, according to the 1st embodiment, includes a laminate 20 in which ceramic layers 21, and internal electrodes 22 composed mainly of metal, are alternately stacked in the T direction, and an element 10, having a protective section 30 covering the surface of laminate 20. Internal electrodes 22 include internal electrodes 22a, with one polarity and which are electrically connected to each other, and internal electrodes 22b, with a polarity different from that of internal electrodes 22a, and which are electrically connected to each other.

Protective section 30 is disposed on the surface of element 10, covering the surface of laminate 20. Protective section 30 includes a cover section 31, disposed on a plane perpendicular to the T direction, and margin sections 32, disposed respectively on a plane perpendicular to the W direction and a plane perpendicular to the L direction.

Element 10 has a plurality of via conductors 23, disposed so as to penetrate ceramic layers 21 in the stacking direction of laminate 20, with at least one end reaching the surface of protective section 30 (cover section 31) and electrically connected to internal electrodes 22. Via conductors 23 include via conductors 23a, electrically connected to internal electrodes 22a, and via conductors 23a, electrically connected to internal electrodes 22b. It should be noted that although multilayer ceramic capacitor 100, shown in FIGS. 1 through 3, has two via conductors 23, the number of via conductors in the multilayer ceramic capacitor according to the 1st aspect of the present invention is not limited to this.

Multilayer ceramic capacitor 100 according to the 1st embodiment has a plurality of terminal electrodes 40 that, among each of the surfaces that make up the front surface of element 10, are disposed on mounting surface 11, which is the surface that faces the circuit board then mounted thereto. Terminal electrodes 40, arranged, on mounting surface 11, include terminal electrodes 40a, electrically connected to via conductors 23a, and terminal electrodes 40b, electrically connected to via conductors 23b. It should be noted that although multilayer ceramic capacitor 100, shown in FIGS. 1 through 3, has two terminal electrodes 40, the number of terminal electrodes in the multilayer ceramic capacitor according to the 1st aspect of the present invention is not limited to this. In addition, although multilayer ceramic capacitor 100 has terminal electrodes 40 (40a, 40b) disposed only on mounting surface 11, the multilayer ceramic capacitor according to the 1st aspect of the present invention may also have terminal electrodes 40 (40a, 40b) disposed on the surface opposite mounting surface 11.

The thickness of element 10, obtained by subtracting the thickness of terminal electrodes 40 (40a, 40b) from the T direction measurement of multilayer ceramic capacitor 100 described above, is, for example 20 μm to 200 μm, and preferably 30 μm to 180 μm.

Each component constituting the multilayer ceramic capacitor 100 according to the 1st embodiment will be described below in detail.

### (Ceramic Layer)

Ceramic layer 21 is formed from a ceramic. The composition of the ceramic is not limited in particular, as long as it forms dense ceramic layers 21 when fired at the same time as internal electrodes 22, which will be described below, and may be chosen appropriately depending on the characteristics required by the multilayer ceramic capacitor. Examples of ceramic compositions include those mainly composed of barium titanate (BaTiO₃), those mainly composed of strontium titanate (SrTiO₃), and those mainly composed of Ba_{1-x-y}CaₓSr_{y}Ti_{1-z}Zr_{z}O₃), which have a perovskite structure. The ceramic may contain an additive element in addition to the main component. Examples of additive elements include at least one selected from among Mo, Nb, Ta, W, Mg, Mn, V, Cr, and rare earth elements (Y, Sm, Eu, Gd, Tb, Dy, Ho, Er, Tm and Yb), as well as Co, Ni, Li, B, Na, K and Si. The additive element may be included as a simple element, or may be included in the form of a compound, such as an oxide, nitride or carbide. The additive element may be present in the state of a solid solution in the main component, or may form a different phase with the element constituting the main component, or with another additive element.

### (Internal Electrode)

Internal electrodes 22 (22a, 22b) are mainly composed of a metal. There is no particular limitation on the type of metal, and nickel (Ni), copper (Cu), palladium (Pd), platinum (Pt), silver (Ag), gold (Au) and alloys thereof may be used. Among these, those containing nickel (Ni) as the main component element are preferred because of its high heat resistance, which allows the firing temperature to be increased when simultaneously firing with ceramic layer 21 to form a dense ceramic layer 21, and because it is relatively inexpensive. Here in this specification, “main component element” means the element with the highest content expressed as an atomic percentage (atomic %).

Internal electrodes 22 (22a, 22b) may contain, in addition to metal, ceramic particles having the same composition as the ceramic constituting ceramic layer 21, or a glass component.

### (Protective Section)

Protective section 30 has the function of protecting ceramic layer 21 and internal electrodes 22. The material of protective section 30 is not limited as long as it is a strong electrical insulator and low permeability to deterioration factors such as moisture. From the standpoint of having uniform shrinkage during firing when manufacturing multilayer ceramic capacitor 100, and alleviating internal stresses within multilayer ceramic capacitor 100, it is preferable that the main component of protective section 30 is the same as the ceramic that forms ceramic layer 21.

### (Via Conductor)

Via conductors 23 (23a, 23b) are mainly composed of metal, similarly to internal electrodes 22 (22a, 22b). Usable metals include those similar to those for internal electrodes 22 (22a, 22b), described above. The composition of the via conductors can be different from that of internal electrodes 22 (22a, 22b), but it is preferable that the composition is the same as that of internal electrodes 22 (22a, 22b). By making via conductors (23a, 23b) and internal electrodes 22 (22a, 22b) with the same composition, the amount of shrinkage cause by firing during the manufacture of the multilayer ceramic capacitor is uniform, which suppresses deformation, and the resistivity of the conduction path of multilayer ceramic capacitor 100 will be uniform, suppressing localized heat generation during use.

The diameter of via conductors (23a, 23b) is not limited in any particular way, but from the viewpoint of ensuring the capacity of multilayer ceramic capacitor 100, while reducing electrical resistance and suppressing heat generation during circuit operation, it is preferable to make the diameter at least 5 μm and no more than 100μm, and more preferably at least 10 μm and no more than 50 μm.

### (Terminal Electrode)

Each of terminal electrodes 40 (40a, 40b) disposed on mounting surface 11 is spaced 10 μm or more from the outer edge of mounting surface 11. By disposing terminal electrodes 40 (40a, 40b) at a sufficient distance from the outer edge of the mounting surface, the circuit board lands, on which multilayer ceramic capacitor 100 is mounted, can be disposed so that they are entirely covered by multilayer ceramic capacitor 100 in a planar view, i.e. so that they do not protrude from multilayer ceramic capacitor 100 in a planar view. This allows the spacing between elements to be narrowed. In addition, when mounting multilayer ceramic capacitor 100 on a circuit board using solder paste, the generation of fillets caused by solder wetting can be suppressed, making it possible to narrow the spacing between the elements. In particular, when multilayer ceramic capacitor 100 is a low-profile MLCC with a measurement of 100 μm or less in the T direction, this is preferable since it significantly suppresses solder wetting that exceeds the height of the element, preventing the circuit board equipped with this form from being unable to be mounted on a motherboard and preventing the occurrence of short circuits during operation. In order to make the effects described above more pronounced, the distance between terminal electrodes 40 (40a, 40b) and the outer edge of mounting surface 11 is preferably 12 μm or more, and more preferably 15 μm or more, and even more preferably 18 μm or more. The upper limit for the spacing between terminal electrodes 40 (40a, 40b) and the outer edge of mounting surface 11 is not limited in particular, but the spacing is preferably 50 μm or less, more preferable 45 μm or less, and even more preferably 40 μm or less. By setting the spacing to be less than or equal to the upper limit value, the area of each terminal electrode 40 (40a, 40b) can be made large enough to easily be mounted on a circuit board, while the spacing between terminal electrodes 40a and 40b, of opposite polarities, can be made wider, thereby improving electrical insulation.

The distance between terminal electrodes 40 (40a, 40b) is preferably 70 μm or more, and more preferably 100 μm or more, and even more preferably 120 μm or more. By setting the spacing to be greater than or equal to the lower limit value, the electrical insulation between terminal electrodes 40a and 40b, of opposite polarities, can be improved. In addition, the spacing between terminal electrodes 40 (40a, 40b) is preferably 400 μm or less, and more preferably 300 μm or less, and even more preferably 200 μm or less. By setting the spacing to be less than or equal to the upper limit value, the area of each terminal electrode 40 (40a, 40b) can be made large enough to easily be mounted on a circuit board. Furthermore, when multilayer ceramic capacitor 100 has a height, the dimension measured in the direction perpendicular to mounting surface 11, of 100 μm or less, having the spacing be less than or equal to the upper limit value results in a significant improvement in mechanical strength. This is presumably because the amount of deformation of element 10, located between terminal electrodes 40 (40a, 40b) is reduced when stress is applied in the height direction.

Here, the spacing between terminal electrodes 40 (40a, 40b) and the outer edge of mounting surface 11 is determined by the following procedure. First, mounting surface 11 of multilayer ceramic capacitor 100 is observed with an optical microscope or a scanning electron microscope (SEM), and an image is obtained, in which the outer edge of mounting surface 11 and one terminal electrode 40 (40a, 40b) adjacent to it appear in the same field of view. Note that multiple terminal electrodes 40 (40a, 40b) may be present in the image, provided that the procedure described below can be carried out on the image obtained. Next, the line segments formed by the outer edge of mounting surface 11 are determined in the image acquired. Here, if the outer edge of mounting surface 11 is curved or meandering, and does not form a line segment, the line segment, obtained by linearly approximating the curve formed by the outer edge, is determined to be the line segment formed by the outer edge. Next, a line segment that is parallel to the determined line segment and that touches the end of the terminal electrode 40 (40a, 40b) on the outer edge side of the element is drawn on the image, and the distance between the drawn line segment and the line segment formed by the outer edge is determined. Next, the measured distance between the two lines is then divided by the magnification at which the observation was made, and the value obtained is used as the distance between terminal electrodes 40 (40a, 40b) and the outer edge of mounting surface 11.

The spacing between terminal electrodes 40 (40a, 40b) is determined by the following procedure. First, mounting surface 11 of multilayer ceramic capacitor 100 is observed with an optical microscope or a scanning electron microscope (SEM), and an image is obtained, in which multiple terminal electrodes 40 (40a, 40b) appear in the same field of view. Next, in the image obtained, the distance between a point located on the contour of one arbitrarily chosen terminal electrode 40 (40a, 40b) and a point located on the contour of another terminal electrode 40 (40a, 40b) closest to the chosen terminal electrode 40 (40a, 40b) is measured, and the combination of contour points that results in the shortest distance is determined. Next, the measured distance between the two points in combination is then divided by the magnification at which the observation was made, and the value obtained is used as the spacing between terminal electrodes 40 (40a, 40b).

The material used for terminal electrodes 40 (40a, 40b) is not limited as long as it is conductive. Examples of materials include metals such as nickel (Ni), copper (Cu), tin (Sn), palladium (Pd), platinum (Pt), silver (Ag), and gold (Au), alloys containing any of these as a main component element, and conductive resins.

Terminal electrodes 40 (40a, 40b) may have an underlying conductor 41 in contact with element 10, and a plated conductor 42, formed on the surface of underlying conductor 41. Terminal electrodes 40 (40a, 40b) having such a structure can improve adhesion to element 10 using underlying conductor 41, while improving solder wettability using plated conductor 42, when mounted on a circuit board.

An example of a material for underlying conductor 41 is Ni. The thickness of underlying conductor 41 may be 0.1 μm or more, and 10 μm or less, and preferably 0.5 μm or more, and 5 μm or less. Underlying conductor 41 is preferably positioned with a spacing of 15 μm or more from the outer edge of mounting surface 11, so that plated conductor 42 can be formed with a sufficient thickness while maintaining the spacing between terminal electrodes 40 (40a, 40b) and the outer edge of mounting surface 11.

Here, the spacing between underlying conductor 41 and the outer edge of mounting surface 11 is determined by the following procedure. First, multilayer ceramic capacitor 100 is cut along a plane perpendicular to mounting surface 11, passing near the center of gravity of the surface parallel to mounting surface 11 of the terminal electrode 40 (40a, 40b) that is closest to the outer edge of mounting surface 11, in order to prepare a sample for observation. This observation sample may be prepared by polishing the surface perpendicular to mounting surface 11 down to the vicinity of said center of gravity. Next, the observation sample is embedded in a resin so that the cut surface is exposed and the cut surface is mirror-polished. The mirror-polished cut surface is then observed under an optical microscope, and one of the two shorter sides of the four sides that form the outer edge of the cut surface is chosen as a reference line, and an image is obtained, in which the reference line and the terminal electrode 40 (40a, 40b) closets to it are in the same field of view. In addition, if the outer edge of the cut surface is curved or meandering, and does not form a side (line segment), the line segment, obtained by linearly approximating the curve formed by the outer edge, is determined to be the side that forms the outer edge. Next, the underlying conductor 41 is determined in the terminal electrode 40 (40a, 40b) portion in the obtained image, based on its difference in hue. Next, a line segment that is parallel to the reference line and tangent to underlying conductor 41 is drawn on the image, and the distance between the drawn line segment and the reference line is measured. The measured distance between both lines is then divided by the magnification at which the observation was made, and the value obtained is used as the spacing between underlying conductor 41 and the outer edge of mounting surface 11.

Plated conductor 42 may be formed with a single layer, or may be formed with a plurality of layers. When plated conductor 42 is formed of a plurality of layers, the number of layers is preferably 2 to 4. An example of the materials and structure of plated conductor 42 is one formed of Cu, Ni, and Sn, in this order. The thickness of plated conductor 42 may be 1 μm or more, and 20 μm or less, and preferably 3 μm or more, and 10 μm or less.

The area of the terminal electrodes 40 (40a, 40b), i.e. the area of terminal electrodes 40 (40a, 40b) observed when multilayer ceramic capacitor 100 is viewed from a direction perpendicular to the mounting surface 11, is not limited in particular, and may be large enough to facilitate mounting on a circuit board, and small enough to prevent electrodes of different polarities from shorting each other out. Preferably, the ratio of the total area for terminal electrodes 40 to the area of mounting surface 11 is 0.2 to 0.9, and more preferably the ratio is 0.3 to 0.8.

### 2nd Embodiment

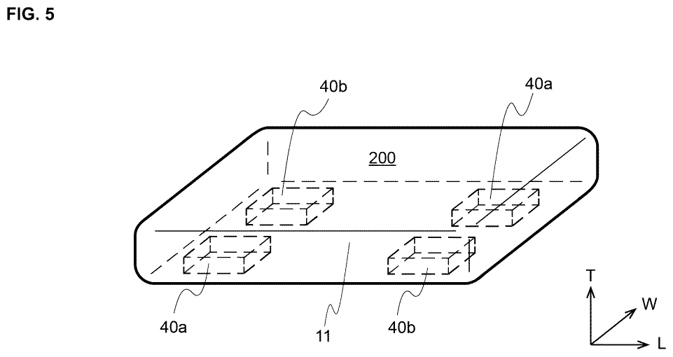

In another embodiment (the 2nd embodiment) of a multilayer ceramic capacitor according to the 1st aspect of the present invention, the number of the plurality of terminal electrodes is at least 4, and each of the terminal electrodes has a polarity different from that of the of the other terminal electrodes closest to it on the mounting surface. FIG. 5 shows an example of multilayer ceramic capacitor 200 according to the 2nd embodiment. It should be noted that although FIG. 5 shows an example in which there are 4 terminal electrodes 40 arranged on mounting surface 11, the number of terminal electrodes disposed on the mounting surface is not limited to this. For multilayer ceramic capacitor 200, the directions of the currents flowing through via conductors 23 (23a, 23b), which are electrically connected to respective terminal electrodes 40 (40a, 40b) are opposite to each other between the nearest via conductors 23 (23a, 23b) and therefore the magnetic fields generated by the currents cancel each other out, thereby reducing ESL. The effect of ESL reduction mentioned above is notable when multilayer ceramic capacitor 200 has two pairs of surfaces that are parallel to the laminate stacking direction and face each other, and the distance between one of them, i.e. the L direction measurement, is L μm, and the distance between the other pair, i.e. the W direction measurement, is W μm (where LEW), and the W/L value, which is the ratio of W to L, is 0.8 or more, and 1 or less, i.e. when mounting surface 11 has a shape close to that of a square.

### 3rd Embodiment

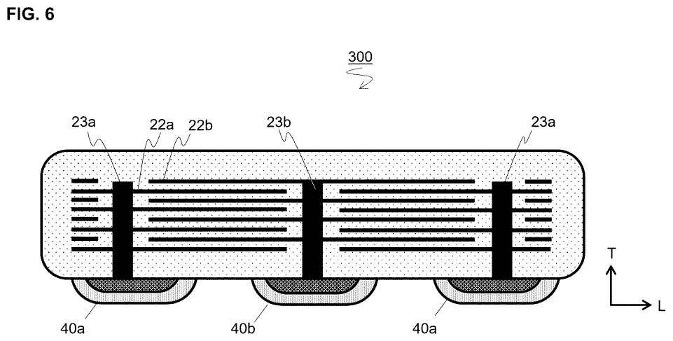

In a further embodiment (the 3rd embodiment) of a multilayer ceramic capacitor according to the 1st aspect of the present invention, 2 or more of said via conductors are electrically connected to at least some of said internal electrodes. FIG. 6 shows an example of multilayer ceramic capacitor 300 according to the 3rd embodiment. It should be noted that, although FIG. 6 shows an example in which 2 via conductors 23a are electrically connected to internal electrodes 22a, and one via conductor 23b is electrically connected to internal electrode 22b, the number of via conductors (23a, 23b) connected to respective internal electrodes 22 (22a, 22b) is not limited to this. In multilayer ceramic capacitor 300, the current flowing through via conductor 23a and internal electrode 22a is reduced, and the magnetic field generated by the current flowing through via conductor 23b can be effectively canceled out by the current flowing through via conductor 23a, which has the advantage of reducing ESL.

### 4th Embodiment

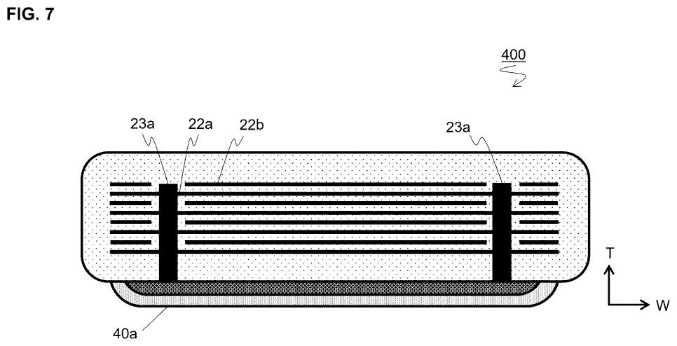

A further embodiment (the 4th embodiment) of a multilayer ceramic capacitor according to the 1st aspect of the present invention, where in the 3rd embodiment described above, at least 1 of the terminal electrodes is electrically connected to 2 or more via conductors. FIG. 7 shows an example of multilayer ceramic capacitor 400 according to the 4th embodiment. It should be noted that although FIG. 7 shows a cross section of a multilayer ceramic capacitor 400, in which two via conductors (23a, 23b) are electrically connected to respective terminal electrodes 40 (40a, 40b), cutting along a plane perpendicular to the L direction, so as to equally divide the L-direction measurement of terminal electrode 40a, the number and disposition of via conductors 23a, 23b, connected to respective terminal electrodes 40 (40a, 40b) are not limited to this. In addition to the ESL elimination effects of the ceramic capacitor according to the 3rd embodiment, multilayer ceramic capacitor 400 has a reduced number of terminal electrodes, which as the advantage of reducing the number of manufacturing steps and facilitates alignment when mounting on a circuit board.

### Method of Manufacture for a Multilayer Ceramic Electronic Component

The multilayer ceramic capacitor according to the 1st aspect of the present invention can be manufacture by the procedure described below.

### ((A) Preparation of the Ceramic Powder)

First, the ceramic powder is prepared. Commercially available ceramic powders can be used as appropriate. When making the ceramic powder in house, various raw material powders containing the constituent elements are mixed at a prescribed ratio and pre-fired (calcinated). When the various raw material powders are mixed in a predetermined ratio, various additives, such as the additive elements mentioned above and sintering aids may also be added, and these various additives may also be added to the powder after calcination.

### ((B) Preparation of Green Sheets)

Next, the ceramic powder described above is mixed with a binder and a dispersion medium in order to prepare a slurry, and the slurry is formed into a sheet in order to obtain a green sheet.

The binder used should be one that can maintain the shape of the green sheet, and that volatilizes without leaving behind carbon or other residues when subjected to a binder removal process prior to firing. Examples of binders that can be used include polyvinyl alcohol, polyvinyl butyral, cellulose, urethane and vinyl acetate binders. There are no particular limitations on the mount of binder used, but since the binder will be removed in a subsequent process, it is preferable to use as little as possible while still achieving the desired formability and shape retention, in order to reduce raw materials costs.

The dispersion medium used should be one that does not cause aggregation of the calcinated powder and binder, and that can easily be removed by volatilization, or other methods, after the forming of a green sheet, as described below. Examples of dispersion media that can be used include water and alcohol-based solvents.

Components for adjusting the properties of the slurry, such as dispersants, plasticizers and thickeners, may be added to the slurry.

The method for mixing the mix powder with the binder and the dispersion medium is not limited in particular, as long as the components are mixed uniformly while preventing the inclusion of impurities. An example of this is ball mill mixing.

The prepared slurry can be formed into a sheet in order to obtain a green sheet, by means of a commonly used method, such as a doctor blade method, or a die coating method.

### ((C) Formation of the Internal Electrode Pattern)

Next, an internal electrode pattern containing metal is formed on the green sheet. The internal electrode pattern can be formed by printing or applying an internal electrode paste in a specified pattern, or by forming a metal film in a specified pattern by means of vapor deposition or sputtering deposition. The internal electrode pattern is formed, leaving a sufficient margin to ensure electrical insulation with the via conductor patterns that are to be formed later and that are not to be brought into contact with each other.

When forming an internal electrode pattern using an internal electrode paste, the internal electrode paste used is obtained by mixing metal particles and a vehicle in a triple roll mill. The internal electrode paste may contain glass frit and ceramic powder in addition to the components mentioned above.

There is no limitation on the type and amount of the binder and solvent contained in the vehicle used, and they may be appropriately selected in consideration of the viscosity of the internal electrode paste, ease of handling, compatibility with the green sheet, etc.

Printing of the internal electrode paste on the green sheets can be done, for example, by using a screen mask on which a predetermined internal electrode pattern is formed. When printing, a space, which will become a margin when the multilayer ceramic capacitor is made, may be left.

### ((D) Preparation of the Green Laminate)

Next, a predetermined number of green sheets, on which the internal electrode pattern is formed, are stacked and the green sheets are pressed together in order to obtain a green laminate. Lamination and pressing can be conducted using a conventional method, and one method that can be used is to press the stacked green sheets together in the direction of stacking while heating them, with thermo-compression bonding by the action of a binder.

During lamination and compression, a green sheet may be added to the end in the direction of stacking to become a cover section when the multilayer ceramic capacitor is formed. In this case, the green sheet added may have the same composition as the green sheet on which the internal electrode pattern is printed, or a different composition. From the viewpoint of having a uniform shrinkage rate during firing, it is preferable that the composition of the added green sheet is the same as, or similar to, the green sheet on which the aforementioned internal electrode precursor is arranged.

### ((E) Formation of the Via Conductor Pattern)

Next, holes are formed in the green laminate, and the holes are filled with a conductor paste to form a via conductor pattern. Conventional methods, such as drilling or lasers, can be used to form these holes. Of these, the use of a laser is preferred, since it can form a smooth processed surface. Conventional methods, such as injection using a syringe or printing using a metal mask, can be used to fill the holes with the conductor paste. Of these, printing using a metal mask is preferred because it is excellent at filling small holes. The components of the conductor paste can be the same as those for the internal electrode paste described above, and the amount of each component can be determined by taking into consideration the ability to fill the holes.

### ((F) Formation of the Terminal Electrode Pattern)

Next, a terminal electrode pattern is formed on at least one of the surfaces (mounting surface) perpendicular to the stacking direction of the green laminate. At this point, a green sheet that will become the cover when the laminate is made into the multilayer ceramic capacitor may be pressed onto the surface on which the terminal electrode pattern is not formed, so as to cover the via conductor pattern. The terminal electrode pattern can be formed by printing or applying a terminal electrode paste, or by forming a metal film by means of vapor deposition or sputtering deposition. At this point, the terminal electrode pattern may be formed using a mask on which a predetermined pattern is formed, or may be formed by forming a paste film or metal film once over the entire mounting surface of the green laminate, and then removing parts other than the terminal electrode pattern. To remove the portions other than the terminal electrode pattern, face milling, barrel polishing, laser processing, or the like may be used. When using a terminal electrode paste to form the terminal electrode pattern, the components can be the same as those for the internal electrode paste described above, and the amount of each component can be determined so that a uniform pattern with the specified thickness is obtained.

### ((G) Preparation of the Pre-Firing Chips)

Next, the green laminate is divided up into individual multilayer ceramic capacitor shapes in order to obtain pre-firing chips. Commonly used means, such as a dicing saw or laser cutter, can be used to make these individual pieces. After the green laminate is made into individual pieces and a surface is formed on which the internal electrode precursor is exposed, the surface can be coated with a material for forming a margin section, and forming a pre-firing chip.

### ((H) Removal of the Binder)

Next, the pre-firing chip obtained is heated in order to volatilize and remove the binder. The heating conditions may be appropriately set to take into consideration the volatilization temperature and contents of the binder. One example is maintaining the chip in a nitrogen (N₂) atmosphere at a temperature of 200 to 500° C. for 5 to 20 hours.

### ((G) Firing of the Pre-Firing Chips)

Next, the pre-firing chips, from which the binder has been removed, are heated to a predetermined temperature and fired. When setting the firing conditions, it is preferable to take into consideration the sinterability of the ceramic powder, as well as the heat resistance and oxidation resistance of the metals contained in the internal electrode pattern, via conductor pattern and terminal electrode pattern. One example of firing conditions is maintaining the chip at a temperature of 1100° C. to 1400° C. for 10 minutes to 2 hours in a reducing atmosphere containing a mixture of nitrogen (N₂), hydrogen (H₂) and water vapor (H₂O). After firing, a reoxidation process can be performed, in which the chip is held at 600° C. to 1000° C. in a nitrogen (N₂) gas atmosphere or a low-oxygen atmosphere.

The sintered body obtained in this way can be used as a multilayer ceramic capacitor as it is, or may be used as a multilayer ceramic capacitor after forming a conductive layer using plating on the surface of the terminal electrode pattern.

### Circuit Board

### 5th Embodiment

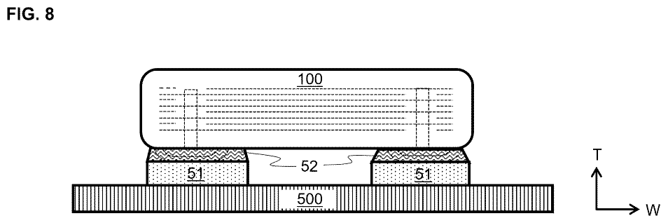

An embodiment of the circuit board according to the 2nd aspect of the present invention will be described as the 5th embodiment, with reference to FIG. 8. Circuit board 500, according to the 5th embodiment, has a multilayer ceramic capacitor 100, relating to the 1st aspect, mounted on it, and lands 51, electrically connected to a plurality of terminal electrodes 40 (40a, 40b). The lands 51 are entirely covered by multilayer ceramic capacitor 100 in a planar view, i.e. when viewed from a direction perpendicular to circuit board 500. In FIG. 8, multilayer ceramic capacitor 100 is mounted on lands 51 of circuit board 500 by means of solder 52. At this point, because land 51 is entirely covered by multilayer ceramic capacitor 100 in a planar view, i.e. because land 51 is located inside the outer edge of mounting surface 11 of multilayer ceramic capacitor 100, the distance to the land (not shown) for connecting other adjacent elements can be made wider than the distance between the elements themselves, so that the distance between adjacent elements can be narrowed, while ensuring electrical insulation between elements. This makes it possible to increase the number of elements that can be mounted in a given space, and reduce the dimensions of the circuit board when the same number of elements of the same size are mounted.

### 6th Embodiment

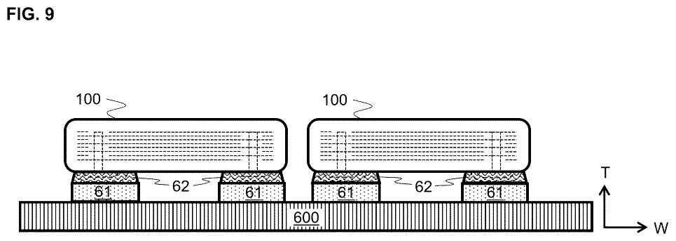

An embodiment of the circuit board according to the 3rd aspect of the present invention will be described with reference to FIG. 9. Circuit board 600, relating to the 6th embodiment, has a plurality of multilayer ceramic capacitors 100, relating to the 1st aspect, mounted upon it, with adjacent multilayer ceramic capacitors 100 spaced apart by 50 μm or less. As shown in FIG. 9, on circuit board 600, relating to the 6th embodiment, when terminal electrodes 40 (40a, 40b) of the multilayer ceramic capacitors 100 are joined to lands 61 by means of solder 62, no fillets are formed due to wetting of solder 62, so that the multilayer ceramic capacitors can be placed close to each other at a distance of 50 μm or less. This makes it possible to increase the number of elements that can be mounted in a given space, and reduce the dimensions of the circuit board when the same number of elements of the same size are mounted.

### WORKING EXAMPLES

The present invention will be described in more detail below with reference to examples, but is not limited to these examples.

### Working Example 1

### (Preparation of Green Sheets)

Pre-fired barium titanate (BaTiO₃) powder was prepared as the ceramic powder. A polyvinyl butyral binder and an alcohol solvent were added to this powder and mixed in a wet ball mill. The resulting mixed slurry was formed with a doctor blade to obtain a green sheet with a thickness of 1 μm.

### (Manufacture of Multilayer Ceramic Capacitor)

An internal electrode paste containing nickel powder as the metal was screen printed on the green sheet obtained in order to form an internal electrode pattern, and then 50 layers of the green sheet were stacked, with 5 green sheets not having the internal electrode paste printed on each of the top and bottom surfaces were then stacked to form covers, and the green laminate was then thermo-compressed to obtain a green laminate. A laser was used to from holes at predetermined positions in this green laminate, and a via conductor formation paste containing nickel powder as its metal was squeegee-packed into the holes through a metal mask. A green sheet for forming the cover was attached to one side of the green laminate filled with the via conductor formation paste, and a terminal electrode forming paste containing nickel powder as its metal was screen-printed on the other side. The screen used in this case was shaped to become the underlying electrode and had a pattern that left as specified spacing from the outer edge of the mounting surface. This green laminate was then cut into individual pieces in order to produce pre-firing chips. The pre-firing chips were heated to 300° C. in a nitrogen atmosphere in order to remove the binder, and then heated to 1200° C. in a so-called reducing/water vapor atmosphere, in which water vapor is introduced into a reducing gas that includes hydrogen in nitrogen, and fired by holding that temperature for 2 hours, when the temperature was then lowered to near room temperature in order to obtained the sintered body. Layers of copper, nickel and tin were formed, in that order, by plating, on the nickel layer present on the surface of the sintered body obtained, that layer formed by sintering the terminal electrode forming paste, thereby obtaining the multilayer ceramic capacitor for Example 1. The multilayer ceramic capacitor obtained had two rectangular electrodes of 250 μm x 480 μm, formed on a rectangular mounting surface of 1000 μm x 500 μm, and spaced 10 μm away from the outer edge of the mounting surface. The T direction measurement of this multilayer ceramic capacitor was 100 μm.

### (Solder Wetting Test)

A solder wetting test was conducted on the multilayer ceramic capacitor for Example 1, in which the capacitor was mounted using solder on a circuit board, on which 250 μm x 480 μm lands were arranged with spacing of 480 μm. The test was conducted on 50 elements, and if no elements had solder fillets, the were considered to have passed. Results are shown in Table 1.

### Working Examples 2 and 3

Multilayer ceramic capacitors according to Examples 2 and 3 were prepared in the same manner as in Example 1, except that the terminal electrodes were two rectangular terminal electrodes of 300 μm×200 μm, formed with a spacing of 15 μm from the outer edge of the mounting surface (Example 2), and two rectangular terminal electrodes of 200 μm×150 μm, formed with a spacing of 20 μm from the outer edge of the mounting surface (Example 3), and solder wetting tests were performed. Results are shown in Table 1.

### Comparative Examples 1 and 2

Multilayer ceramic capacitors according to Comparative Examples 1 and 2 were prepared in the same manner as in Example 1, except that the terminal electrodes were two rectangular terminal electrodes of 260 μm×500 μm, formed in contact with the outer edge of the mounting surface (Comparative Example 1), and two rectangular terminal electrodes of 225 μm×490 μm, formed with a spacing of 5 μm from the outer edge of the mounting surface (Comparative Example 2), and solder wetting tests were performed. Results are shown in Table 1.

TABLE 1

| | Spacing from | | |
|---|---|---|---|
| | Mounting | No. of Elements | |
| | Surface Outer | for which Solder | |
| | Edge | Wetting Occurred | |
| | [μm] | [Units] | Passed/Failed |
| Comparative | 0 | 30 | Failed |
| Example 1 | | | |
| Comparative | 5 | 10 | Failed |
| Example 2 | | | |
| Working | 10 | 0 | Passed |
| Example 1 | | | |
| Working | 15 | 0 | Passed |
| Example 2 | | | |
| Working | 20 | 0 | Passed |
| Example 3 | | | |

It can be seen from these results that in the multilayer ceramic capacitor according to the embodiment in which the plurality of terminal electrodes formed on the mounting surface are all spaced at least 10 μm from the outer edge of the mounting surface, fillets due to solder wetting do not form when mounted on a circuit board. On the other hand, in the multilayer ceramic capacitor according to the comparative example, in which the spacing between the terminal electrodes formed on the mounting surface and the outer edge of the mounting surface is less than 10 μm, fillets may form when mounted on a circuit board.

This specification also discloses the following art.

### Supplementary Note 1

A multilayer ceramic capacitor comprising:
a rectangular solid element having
   a laminate in which ceramic layers and internal electrodes mainly composed of metal are stacked alternately,
   a protective section covering the surface of said laminate, and
   a plurality of via conductors, disposed so as to penetrate said ceramic layers in the stacking direction of said laminate, at least one end of which reaches the surface of said protective section and is electrically connected to said internal electrodes and
a plurality of terminal electrodes disposed on a mounting surface that, among the surfaces that form the front surface of said element, faces a circuit board when mounted on said circuit board;
   wherein
   each of said plurality of terminal electrodes is electrically connected to said via conductor and arranged with a spacing of 10 μm or more from the outer edge of said mounting surface.

### Supplementary Note 2

The multilayer ceramic capacitor according to (supplementary note 1), wherein for said outer edge, the contour of said mounting surface is viewed in an optical microscope image or a scanning electron microscope (SEM) image acquired from a vertical direction about the mounting surface, and determined by approximating it to a rectangle.

### Supplementary Note 3

The multilayer ceramic capacitor according to (supplementary note 1) or (supplementary note 2), wherein said plurality of terminal electrodes each have an underlying conductor in contact with said element and a plated conductor formed on the surface of said underlying conductor, and wherein the underlying conductor is arranged with a spacing of 15 μm or more from the outer edge of said mounting surface.

### Supplementary Note 4

The multilayer ceramic capacitor according to any one of (supplementary notes 1) to (supplementary note 3), wherein the height, which is the dimension in the direction perpendicular to the said mounting surface, is 100 μm or less.

### Supplementary Note 5

The multilayer ceramic capacitor according to any one of (supplementary note 1) to (supplementary note 4), wherein the spacing between said plurality of terminal electrodes, is 400 μm or less.

### Supplementary Note 6

The multilayer ceramic capacitor according to any one of (supplementary note 1) to (supplementary note 5), wherein the number of said plurality of terminal electrodes is at least four, and each of the terminal electrodes has a polarity different from that of the closest other terminal electrodes on said mounting surface.

### Supplementary Note 7

The multilayer ceramic capacitor according to any one of (supplementary note 1) to (supplementary note 6), wherein two or more of said via conductors are electrically connected to at least some of said internal electrodes.

### Supplementary Note 8

The multilayer ceramic capacitor according to (supplementary note 7), wherein two or more of said via conductors are electrically connected to at least one of said internal electrodes.

### Supplementary Note 9

A circuit board carrying the multilayer ceramic capacitor according to any one of (supplementary note 1) to (supplementary note 8), wherein the lands, which are electrically connected to said plurality of terminal electrodes, are entirely covered by the multilayer ceramic capacitor in a planar view.

### Supplementary Note 10

A circuit board carrying a plurality of the multilayer ceramic capacitors according to any one of (supplementary note 1) to (supplementary note 8), wherein the spacing between adjacent multilayer ceramic capacitors is 50 μm or less.

### INDUSTRIAL APPLICABILITY

According to the present invention, it is possible to provide a multilayer ceramic capacitor that enables narrow element spacing when mounted on a circuit board, and a circuit board on which the mounted elements are mounted with a narrow spacing. Such multilayer ceramic capacitors and circuit board are useful in that they contribute to the miniaturization of electronic devices incorporating high-performance semiconductors.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A multilayer ceramic capacitor comprising:
a rectangular solid element having
a laminate in which ceramic layers and internal electrodes mainly composed of metal are stacked alternately,
a protective section covering the surface of said laminate, and
a plurality of via conductors, disposed so as to penetrate said ceramic layers in the stacking direction of said laminate, at least one end of which reaches the surface of said protective section and is electrically connected to said internal electrodes and
a plurality of terminal electrodes disposed on a mounting surface that, among the surfaces that form the front surface of said element, faces a circuit board when mounted on said circuit board;
wherein
each of said plurality of terminal electrodes is electrically connected to said via conductor and arranged with a spacing of 10 μm or more from the outer edge of said mounting surface.

2. The multilayer ceramic capacitor according to claim 1, wherein for said outer edge, the contour of said mounting surface is viewed in an optical microscope image or a scanning electron microscope (SEM) image acquired from a vertical direction about the mounting surface, and determined by approximating it to a rectangle.

3. The multilayer ceramic capacitor according to claim 1, wherein said plurality of terminal electrodes each have an underlying conductor in contact with said element and a plated conductor formed on the surface of said underlying conductor, and wherein the underlying conductor is arranged with a spacing of 15 μm or more from the outer edge of said mounting surface.

4. The multilayer ceramic capacitor according to claim 1, wherein the height, which is the dimension in the direction perpendicular to the said mounting surface, is 100 μm or less.

5. The multilayer ceramic capacitor according to claim 4, wherein the spacing between said plurality of terminal electrodes, is 400 μm or less.

6. The multilayer ceramic capacitor according to claim 1, wherein the number of said plurality of terminal electrodes is at least four, and each of the terminal electrodes has a polarity different from that of the closest other terminal electrodes on said mounting surface.

7. The multilayer ceramic capacitor according to claim 1, wherein two or more of said via conductors are electrically connected to at least some of said internal electrodes.

8. The multilayer ceramic capacitor according to claim 7, wherein two or more of said via conductors are electrically connected to at least one of said internal electrodes.
